(19) United States
(12) Patent Application Publication
(10) Pub. No.: US 2002/0131259 A1
(43) Pub. Date: Sep. 19, 2002

(54) Enclosure teeth/recesses used for robust electromagnetic compatibility design

(76) Inventors: Yoram Rozy, Danville, CA (US); Jeffrey A. Griffis, Redwood City, CA (US); Hong Li, San Ramon, CA (US)

Correspondence Address: Bruce H. Johnsonbaugh, Eckhoff, Hoppe, Slick, Mitchell & Anderson, Suite 3125, 333 Market Street, San Francisco, CA, 94105, US

(21) Appl. No.: 09/810,200

(22) Filed: Mar. 15, 2001

(51) Int. Cl. H05K 9/00

(52) U.S. Cl. 361/818

(57) ABSTRACT

A method of EMI shielding the seam(s) of a multiple-part enclosure is provided herein. The enclosure can be produced and assembled quickly and inexpensively. An embodiment of the invention is formed of two conductive sheet metal parts that make up the outer enclosure of an optoelectronic transceiver. The parts come together in a way that allows for an interference fit, and requires a press fit operation for complete engagement. A series of recesses along the edge of one part and a series of oversized (in relation to the recesses) teeth in the other part provide the interference fit. The oversized teeth are pressed into the recesses, providing metal-to-metal contact at regular intervals along the interface. Contact at regular intervals provides a robust EMI shield against electromagnetic waves incident to the enclosure's interior or exterior.

### CROSS-REFERENCE TO RELATED APPLICATION

This application is a continuation-in-part of U.S. Patent Application No. ______ titled “Optical Wavelength Division Multiplexer and/or Demultiplexer Mounted in a Pluggable Module,” filed on Mar. 12, 2001, and incorporated herein by reference.

### BACKGROUND OF THE INVENTION

1. Field of the Invention

The invention relates generally to enclosures for electronic or optoelectronic assemblies and more specifically, it relates to an inexpensive and easily manufacturable enclosure that prevents exterior electronic signals from disrupting or interfering with interior electronic signals and also prevents interior electronic signals from disrupting or interfering with exterior electronic signals.

2. Description of Related Art

It is important that current electronic assemblies be robustly designed to minimize or eliminate problems caused by Electromagnetic Interference (EMI). If an electronic assembly is not properly shielded or enclosed with respect to its environment with a conducting material, electrical signals of varying frequency within the assembly may disrupt other electronic systems outside the assembly or vice versa. Of course, this is a challenging problem, as most electronic assembly enclosures must have apertures for input/output, power, etc.

A variety of methodologies have been provided concerning EMI shielding. For example, U.S. Pat. No. 6,178,096, titled “Shielding Cover Having Parts Held Together By Latch Members” describes a shielding cover for a GBIC module including a pair of cover parts formed with complementary features to surround a printed circuit board of the module. A pair of latch members hold the two cover parts together and also provide a latching function when a module is inserted into a guide structure mounted to a host board.

U.S. Pat. No. 5,566,052, titled “Electronic Devices With Electromagnetic Radiation Interference Shields And Heat Sinks” describes an electronic device with an EMI shield surrounding an electronic component on a substrate. A heat sink extends through an opening in the shield from a heat conductive contact with the component to a position outside the shield. The heat sink operates also in an EMI shield capacity. The shield is stressed to hold the heat sink positively in heat conducting contact with the components. The shield preferably has cutting teeth that cut into the heat sink as the latter is passed into the aperture. With the inserted part of the heat sink being cylindrical, rotation of the heat sink causes the teeth to move up the inserted part to stress the shield and urge the heat sink against the component.

U.S. Pat. No. 6,194,653, titled “Enclosure Design Having An Integrated System Of Retention, Electromagnetic Interference Containment And Structural Load Distribution” describes a metal enclosure formed of three basic parts of stamped sheet metal. The parts include a system of retention clips, spring fingers and embossed dimples to achieve easy assembly and a high level of electromagnetic interference containment when the parts are assembled. The design also provides high structural rigidity, mechanical strength and ease of assembly/disassembly.

U.S. Pat. No. 6,188,017, titled “Electromagnetic Interference (EMI) Shielding Apparatus” is directed to an apparatus and method for shielding electromagnetic interference (EMI) and includes a circuit board assembly having a bracket and a circuit board attached to the bracket. The circuit board includes a connector for insertion through an opening in the bracket. A compressible member having an outer conductive portion is positioned between the connector and an inner surface of the bracket to prevent passage of electromagnetic interference.

It would be desirable to have an EMI shielding apparatus that provides a simple and cost effective EMI shield.

### SUMMARY OF THE INVENTION

In view of the above, it is the object of this invention to provide an enclosure that can be separated into parts as needed to facilitate assembly and still prove effective for EMI shielding.

It is another object of this invention to provide an enclosure that can be produced and assembled quickly and inexpensively.

It is another objective of this invention to provide an enclosure that can be disassembled and then reassembled repeatably.

These and other objects will be apparent based on the teachings herein.

An embodiment of the invention is formed of two conductive sheet metal parts that make up the outer enclosure of an optoelectronic transceiver. The parts come together in a way that allows for an interference fit, and requires a press fit operation for complete engagement.

A series of recesses along the edge of one part and a series of oversized (in relation to the recesses) teeth in the other part provide the interference fit. To engage the two parts together, the oversized teeth are pressed into the recesses, providing metal-to-metal contact at regular intervals along the interface of the two parts. Such metal-to-metal contact at regular intervals provides a robust EMI shield against electromagnetic waves incident to the interior or exterior of the enclosure.

One specific embodiment is made of aluminum sheet metal. A two-part enclosure with interference fit features contains the electronics portion of a transceiver package.

The invention may take many forms and can be made of any number of parts. At least one of the parts must have recesses into which slightly larger features of at least one other part may be press fit. To effectively prevent EMI from entering or exiting the enclosure, the parts of the enclosure are made of a conductive material. The parts may be cut and formed from sheet material stock. The teeth and recesses in each part must be spaced at predetermined intervals to provide a robust housing with respect to EMI shielding effectiveness.

### BRIEF DESCRIPTION OF THE DRAWINGS

FIG. 1A illustrates the use of a two part housing to enclose the optoelectronics portion of a transceiver assembly.

FIG. 1B shows top aluminum cover after it has been placed onto the guide rails of a plastic transceiver housing.

FIG. 1C shows the rear anchor tabs of a bottom aluminum cover as they are next placed between the top aluminum cover and the rear flange of a plastic transceiver housing.

FIG. 1D shows the assembled configuration of FIGS. 1 A-C.

FIG. 2A shows a top aluminum cover mated to a bottom aluminum cover.

FIG. 2B is an enlarged view of the circled area of FIG. 2A and demonstrates the tight press fit of the bottom aluminum cover teeth into the top aluminum cover recesses.

### DETAILED DESCRIPTION OF THE INVENTION

In one form of the invention, two aluminum sheet metal parts make up the outer enclosure of an optoelectronic transceiver. The sheet metal parts come together in a north-south fashion, enclosing the electronics between them. The two parts contain features that allow for an interference fit of the two parts, necessitating a press fit operation for complete engagement.

The features that provide the interference fit are a series of recesses in the flange of one part and a series of oversized (in relation to the recesses) teeth in the other part. When the two parts come together, the oversized teeth are pressed into the recesses, thus ensuring metal-to-metal contact at regular intervals along the interface of the two parts.

It is the metal-to-metal contact at regular intervals that provides a robust EMI shield against electromagnetic waves incident to the interior or exterior of the enclosure. Without the regular contact, the interface of the two parts would act as a much larger seam. Because EMI shielding effectiveness of an enclosure is directly proportional to the size of the enclosure's apertures, the much larger seam would be catastrophic to the design.

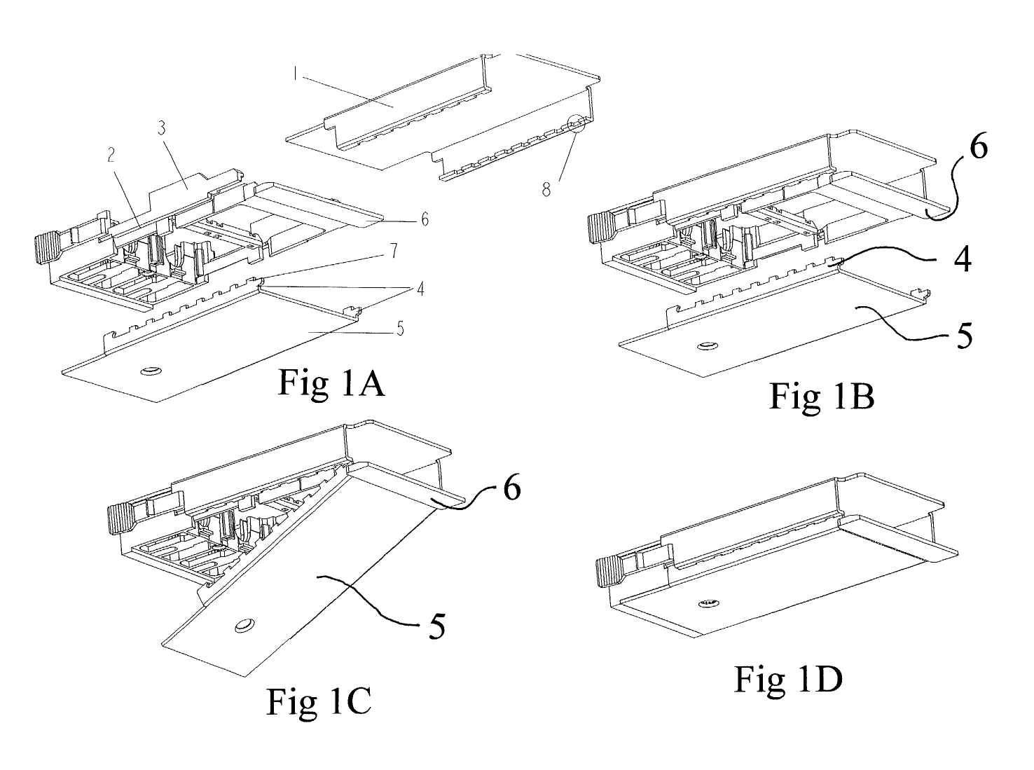

FIG. 1A illustrates the use of a two-part enclosure with interference fit features to contain the electronics portion of a transceiver package. Top aluminum cover 1 first slides onto guide rails 2 of plastic transceiver housing 3. See FIG. 1 B. The rear anchor tabs 4 of bottom aluminum cover 5 are next placed between top aluminum cover 1 and rear flange 6 of plastic transceiver housing 3 as shown in FIG. 1C.

Bottom aluminum cover 5 is next rotated towards plastic transceiver housing 3, forcing bottom aluminum cover teeth 7 into the top aluminum cover recesses 8. Force is then applied in a direction normal to the largest surface of both covers in order to achieve maximum teeth/recess engagement. FIG. 1D shows the assembled configuration.

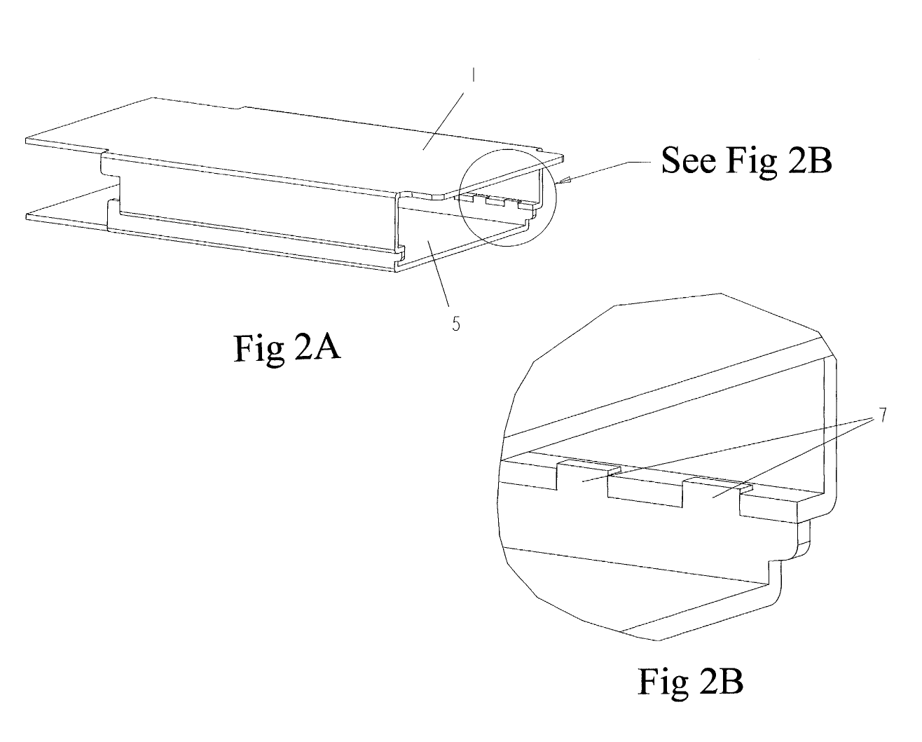

FIG. 2A shows top aluminum cover 1 mated to bottom aluminum cover 5. FIG. 2B is an enlarged view of the circled area of FIG. 2A and demonstrates the tight press fit of the bottom aluminum cover teeth 7 into the top aluminum cover recesses 8 (not pointed out in FIG. 2).

It should be recognized that the invention may take many forms. The invention is an enclosure comprised of any number of parts. It is required that at least one of the parts have recesses into which slightly larger features of at least one other part may be press fit. To effectively shield EMI from entering or exiting the enclosure, the parts of the enclosure are made of a conductive material. The parts may be cut and formed from sheet material stock. The teeth and recesses in each part must be spaced at predetermined intervals to provide a robust housing with respect to EMI shielding effectiveness. The housing is openable and closable by hand. The pressed fit teeth provide increased torsional and structural rigidity to the housing.

Examples of optoelectronic transceivers that can be housed within the shielded enclosure of the present invention are described in the parent application and in commonly owned U.S. Pat. No. 6,201,908, titled “Optical Wavelength Division Multiplexer/ Demultiplexer Having Preformed Passively Aligned Optics,” incorporated herein by reference. Still other optoelectronic transceivers that could benefit from the shielding provided by the present invention are known in the art.

The foregoing description of the invention has been presented for purposes of illustration and description and is not intended to be exhaustive or to limit the invention to the precise form disclosed. Many modifications and variations are possible in light of the above teaching. The embodiments were chosen and described to best explain the principles of the invention and its practical application to thereby enable others skilled in the art to best use the invention in various embodiments and with various modifications suited to the particular use contemplated. The scope of the invention is to be defined by the following claims.

What is claimed is:

1. An electromagnetic interference (EMI) shielding seam, comprising a first part having teeth and a second part having recesses formed to receive said teeth.

2. The EMI shielding seam of claim 1, wherein said teeth are slightly larger than said recesses, wherein said teeth may be press fit into said recesses.

3. The EMI shielding seam of claim 1, wherein said first part and said second part both comprise conductive material.

4. The EMI shielding seam of claim 1, wherein said teeth and said recesses in each part are spaced at predetermined intervals.

5. The EMI shielding seam of claim 1, wherein said first part and said second part each comprise sheet material stock.

6. The EMI shielding seam of claim 1, wherein said first part and said second part comprise an enclosure for a transceiver.

7. The EMI shielding seam of claim 1, wherein said first part and said second part comprise aluminum.
